(19) United States
(12) Patent Application Publication
(10) Pub. No.: US 2015/0185287 A1
(43) Pub. Date: Jul. 2, 2015

(54) DETECTION DEVICE FOR POWER COMPONENT DRIVERS, AND DETECTION METHOD THEREOF

(71) Applicant: INDUSTRIAL TECHNOLOGY RESEARCH INSTITUTE, Hsinchu (TW)

(72) Inventors: Yung-Chen WANG, Kaohsiung (TW); Shih-Hsiang CHIEN, Yilan County (TW); Chin-Hone LIN, Nantou County (TW); Hsieh-Tai SU, New Taipei (TW)

(73) Assignee: INDUSTRIAL TECHNOLOGY RESEARCH INSTITUTE, Hsinchu (TW)

(21) Appl. No.: 14/244,717

(22) Filed: Apr. 3, 2014

(30) Foreign Application Priority Data
Dec. 27, 2013 (TW) 102148865

(51) Int. Cl. G01R 31/327; G01R 31/34; G01R 31/40

(52) U.S. Cl. CPC G01R 31/327; G01R 31/40; G01R 31/34

(57) ABSTRACT

A detection device for power component drivers, and a detection method thereof are provided, where the detection device determine the state of a plurality of upper arm switches and the state of a plurality of under arm switches in a power component driver when different stages of a detection procedure are performed on the upper arm switches and the under arm switches. The detection device then performs a protection procedure according to the state of the upper arm switches and the state of the under arm switches.

### CROSS-REFERENCE TO RELATED APPLICATIONS

This non-provisional application claims priority under 35 U.S.C. §119(a) on Patent Application No(s). 102148865 filed in Taiwan, R.O.C. on Dec. 27, 2013, the entire contents of which are hereby incorporated by reference.

### TECHNICAL FIELD

This disclosure relates to a detection device for power component drivers, and a detection method thereof.

### BACKGROUND

When switching transistors in a motor driver of a motor have received a great load current for a long time, the solders of the switching transistors might fall off or float. This may cause the switching transistors to be short-circuited and disconnected, resulting in the failure to drive the motor. More severely, the motor driver and the motor may burn out because of the over-discharging of a battery related to the motor, which can be dangerous to users.

### SUMMARY

According to one or more embodiments, the disclosure provides a detection device. In one embodiment, the detection device is coupled with a direct current (DC) power source, a storage module, a power component driver, and a motor. The power component driver comprises a plurality of switch sets. Each of the plurality of switch sets comprises at least one upper arm switch and at least one under arm switch. The detection device comprises a DC measuring module, a control module, and a signal detection module. The DC measuring module is coupled with the storage module and configured to measure a voltage of the storage module to generate a first detection signal. The control module is coupled with the DC measuring module and the power component driver and configured to determine whether the plurality of switch sets are short-circuited, according to the first detection signal. When the plurality of switch sets are not short-circuited, and the control module selects and enables the at least one upper arm switch or the at least one under arm switch of one of the plurality of switch sets. The signal detection module is coupled with the power component driver and the motor, and configured to convert a voltage, which is supplied by the plurality of switch sets to drive the motor, to generate a second detection signal according to which the control module determines whether the selected upper arm switch or under arm switch malfunctions.

According to one or more embodiments, the disclosure provides a detection method for determining whether a power component driver, which is coupled with a motor and a DC power source, malfunctions. In one embodiment, the detection method comprises the following steps. Firstly, a voltage of a storage module is measured to generate a first detection signal, and the storage module is coupled with an input end of the power component driver. According to the first detection signal, whether a plurality of switch sets in the power component driver are short-circuited is determined. Each of the plurality of switch sets comprises at least one upper arm switch and at least one under arm switch. When the plurality of switch sets are not short-circuited, the at least one upper arm switch or the at least one under arm switch of one of the plurality of switch sets is selected and enabled. Then, a voltage, which is provided by the plurality of switch sets to drive the motor, is converted to a second detection signal. Finally, whether the selected upper arm switch or the selected under arm switch malfunctions is determined according to the second detection signal.

According to one or more embodiments, the disclosure provides another detection device. In one embodiment, the detection device is coupled with a DC power source, a power component driver, and a motor. The power component driver comprises a plurality of switch sets. Each of the plurality of switch sets comprises a plurality of upper arm switches in parallel connection and a plurality of under arm switches in parallel connection. The detection device comprises a control module and a signal detection module. The control module is coupled with the power component driver, and configured to select and enable the upper arm switches of one of the plurality of switch sets and the under arm switches of other one of the plurality of switch sets when the plurality of switch sets are not short-circuited. The input end of the signal detection module is coupled with the power component driver and the motor, and the output end of the signal detection module is coupled with the control module. The signal detection module is configured to convert a voltage, which is provided by the plurality of switch sets to drive the motor, to generate a first detection signal when the plurality of switch sets are not short-circuited. The control module determines whether the selected upper arm switches or the selected under arm switches malfunction, according to the first detection signal.

According to one or more embodiments, the disclosure provides another detection method for determining whether a power component driver malfunctions. The power component driver is coupled with a motor and a DC power source and comprises a plurality of switch sets. Each of the plurality of switch sets comprises a plurality of upper arm switches in parallel connection and a plurality of under arm switches in parallel connection. In one embodiment, the detection method comprises the following steps. Firstly, the upper arm switches of one of the plurality of switch sets and the under arm switches of other one of the plurality of switch sets are selected and enabled when the switch sets are not short-circuited. Then, a voltage, which is provided by the plurality of switch sets to drive the motor, to generate a first detection signal. Finally, whether the selected upper arm switches and the selected under arm switches malfunction is determined according to the first detection signal.

### BRIEF DESCRIPTION OF THE DRAWINGS

The disclosure will become more fully understood from the detailed description given herein below for illustration only, and thus are not limitative of the disclosure, and wherein:

FIG. 1 is a block diagram of a detection system of a power component driver in an embodiment in the disclosure;

FIG. 2 is a schematic circuit diagram of the slow-start module in FIG. 1;

FIG. 3 is a schematic circuit diagram of the signal detection module in FIG. 1;

FIG. 4 is a waveform diagram of voltages outputted by the signal detection module in FIG. 1; and

FIG. 5 is a flow chart of a detection method of a power component driver in an embodiment in the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

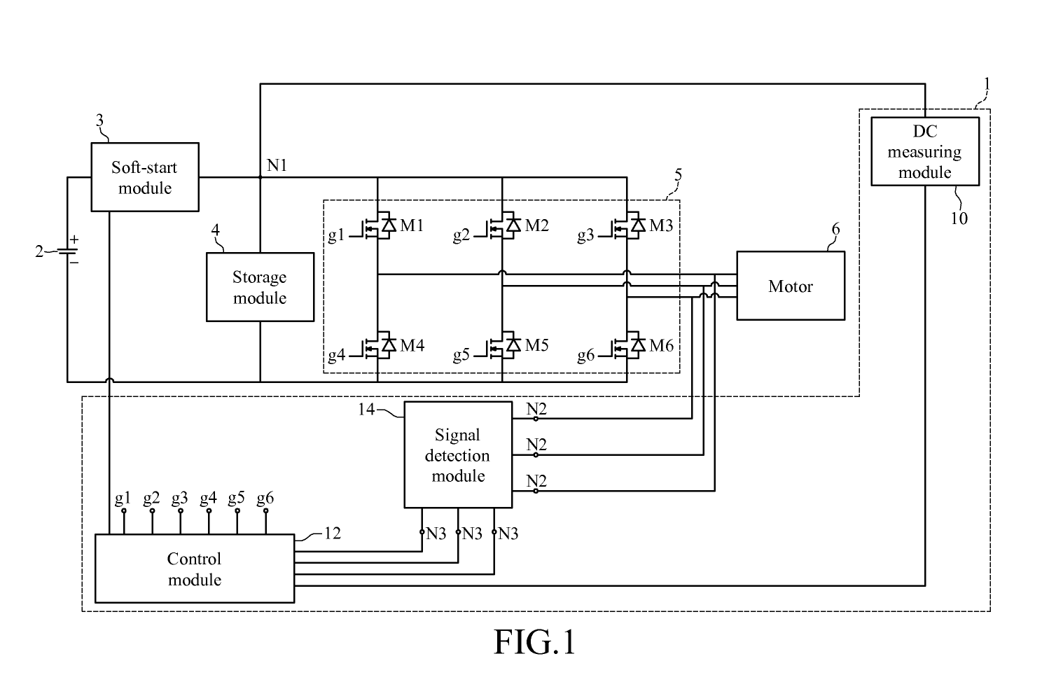

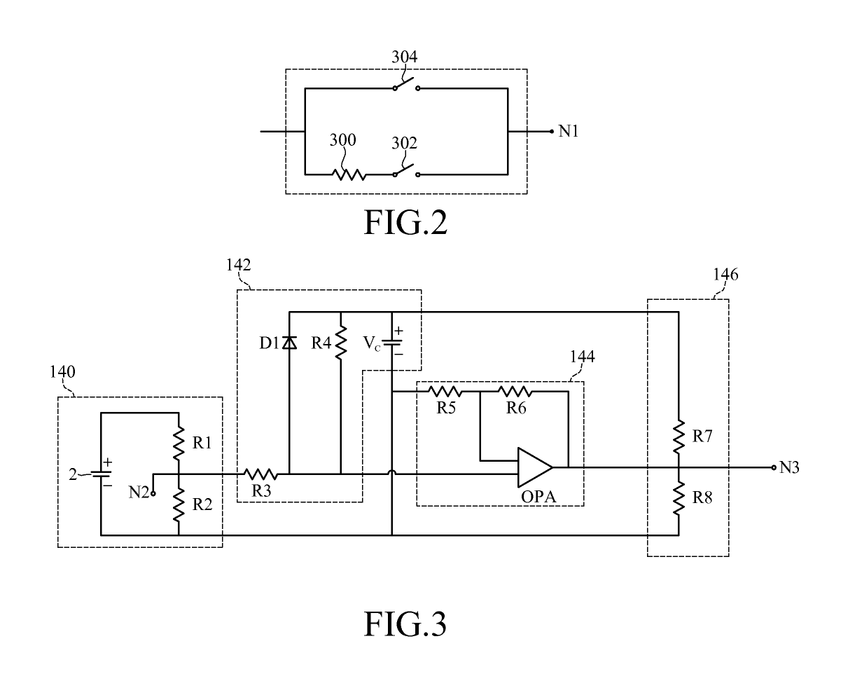

Referring to FIG. 1 and FIG. 2, one or more embodiments of a detection system for power component drivers and one or more embodiments of a slow-start module 3 in FIG. 1 are illustrated. As shown in FIG. 1, the detection system comprises a detection device 1, a direct current (DC) power source 2, the soft-start module 3, a storage module 4, a power component driver 5, and a motor 6. The detection device 1 comprises a DC measuring module 10, a control module 12, and a signal detection module 14. The detection system may be able to be applied to electric vehicles and products with variable-frequency drives (VFD), and for example, the products with variable-frequency drives are air-conditioners, refrigerators, or power supply modules.

For example, the motor 6 is a three-phase motor. Since the disclosure does not have any limitation on the verity of the power component driver 5 which the detection device 1 is adapted to, the power component driver 5 may be a multi-phase motor drive control circuit such as a three-phase motor drive control circuit. The power component driver 5 comprises three switch sets. Each switch sets comprises an upper arm switch M1, M2 or M3, and an under arm switch M4, M5 or M6 corresponding to the upper arm switch M1, M2 or M3. Furthermore, in FIG. 1, the upper arm switches M1 to M3 and the under arm switches M4 to M6 are only an example. In other words, the disclosure does not intend to have limitations on the number of switching transistors in the upper arm switches M1 to M3 and the under arm switches M4 to M6. If each of the upper arm switches M1 to M3 or each of the under arm switches M4 to M6 comprises a plurality of switching transistors inside, the switching transistors in the upper arm switch or the under arm switch are in parallel connection. Since the operation of the power component driver 5 and the motor 6 is well-known in the art, it will not be discussed hereinafter.

One end of the slow-start module 3 is coupled with the positive end (+) of the DC power source 2, and the other end of the slow-start module 3 is coupled with the DC measuring module 10, the storage module 4, and the input end N1 of the power component driver 5 respectively. The DC measuring module 10 is coupled with the input end N1 of the power component driver 5 and the control module 12. The output end of the power component driver 5 is coupled with the motor 6. The input ends N2 of the signal detection module 14 are coupled with the coiling between the power component driver 5 and the motor 6. In other words, the input ends N2 of the signal detection module 14 are coupled with the three-phase voltage ends of the motor 6. The output ends N3 of the signal detection module 14 are coupled with the control module 12. Moreover, the control module 12 is coupled with the slow-start module 3, and the control ends g1 to g3 of the upper arm switches M1 to M3 and the control ends g4 to g6 of the under arm switches M4 to M6 in the power component driver 5. All the different modules in the detection system are illustrated below.

As shown in FIG. 2, the slow-start module 3 comprises an impedance unit 300, a first switching unit 302, and a second switching unit 304. The impedance unit 300 is coupled with the first switching unit 302 and the DC power source 2. The first switching unit 302 and the impedance unit 300 in series connection are in parallel connection with the second switching unit 304. Therefore, when the first switching unit 302 is turned on, the impedance unit 300 and the turned-on first switching unit 302 provide a first current path. When the second switching unit 304 is turned on, the turned-on second switching unit 304 provides a second current path. For example, the first switching unit 302 and the second switching unit 304 are metal oxide semiconductor field effect transistors (MOSFET), relays, or series resonant converters (SRC), but the disclosure is not limited thereto. The first switching unit 302 and the second switching unit 304 in FIG. 2 in the slow-start module 3 in FIG. 1 may be controlled by the control signal (not shown in FIG. 2) outputted by the control module 12.

The storage module 4 may store the DC voltage provided by the DC power source 2. In more detail, the storage module 4 may store the voltage of the input end N1 of the power component driver 5 when the first switching unit 302 is turned on and the switch sets in the power component driver 5 are not short-circuited. For example, the storage module 4 is an energy storage capacitor or an energy storage inductor, but the disclosure is not limited thereto.

The DC measuring module 10 may measure the voltage of the storage module 4 to generate a first detection signal. Moreover, the DC measuring module 10 may measure the current flowing through the first current path, to generate the first detection signal. In other words, the first detection signal may specify the voltage of the storage module 4 and specify the current flowing through the first current path.

The control module 12 may, according to the first detection signal, determine whether any of the switch sets in the power component driver 5 becomes short-circuited in the first stage of the detection process and determine whether the slow-start module 3 functions normally. In more detail, when the control module 12 determines that the voltage of the storage module 4 is at a high level, the control module 12 may determine that each of the switch sets in the power component driver 5 is not short-circuited, so that the power component driver 5 may be unlikely to create danger when driving the motor 6. When the control module 12 determines that the voltage of the storage module 4 is at a low level, the control module 12 may determine that at least one of the switch sets in the power component driver 5 is short-circuited, so that the power component driver 5 is likely to create danger when driving the motor 6.

The control module 12 may control the switching-on-and-off of the first switching unit 302 and the second switching unit 304 in the slow-start module 3. When the control module 12 determines that one of the switch sets in the power component driver 5 is short-circuited, the control module 12 may turn off the first switching unit 302 and the second switching unit 304 in the slow-start module 3. In contrast, when the control module 12 determines that each of the switch sets in the power component driver 5 is not short-circuited, the control module 12 may select and enable the upper arm switch or the under arm switch in one of the switch sets in the second stage of the detection process and turn on the second switching unit 304.

The signal detection module 14 may convert the voltage (i.e. the three-phase voltage), which is provided by the switch sets to drive the motor 6, to generate a second detection signal when each of the switch sets in the power component driver 5 is not short-circuited. Thus, the control module 12 may determine whether the selected upper arm switch or the under arm switch malfunctions, according to the second detection signal.

To more clearly illustrate the operation of the signal detection module 14, FIG. 3 illustrates a circuit diagram of the signal detection module 14 in FIG. 1. The signal detection module 14 comprises at least one circuit shown in FIG. 3. For example, the number of the at least one circuit shown in FIG. 3 in the signal detection module 14 is three. The input ends N2 and the output ends N3 of the three circuits in FIG. 3 are coupled with the three input ends N2 and the three output ends N3 in FIG. 1 respectively. In one of the embodiments, the signal detection module 14 may comprise one circuit shown in FIG. 3 and two three-stage switch sets, but the disclosure is not limited thereto.

As shown in FIG. 3, each circuit of the signal detection module 14 comprises a voltage division circuit 140, a bias voltage adjustment circuit 142, a gain adjustment circuit 144, and a mid-point adjustment circuit 146. The voltage division circuit 140 is coupled with the bias voltage adjustment circuit 142. The bias voltage adjustment circuit 142 is coupled with the gain adjustment circuit 144 and the mid-point adjustment circuit 146. The voltage division circuit 140 comprises a resistor R1, a resistor R2, and a DC power source 2. The input end N2 of the signal detection module 14 is the node where the resistor R1 connects to the resistor R2. The voltage division circuit 140 may adjust the voltage inputted by the input end N2 proportionally to prevent that the power component driver 5 directly outputs a high voltage to an operational amplifier OPA of the gain adjustment circuit 144.

The bias voltage adjustment circuit 142 comprises a resistor R3, a resistor R4, a diode D1, and a DC power source Vc. One end of the resistor R3 is coupled with the input end N2, and the other end of the resistor R3 is coupled with the resistor R4 and the anode of the diode D1. The resistor R4 and the diode D1 are in parallel connection. The cathode of the diode D1 is coupled with the positive end (+) of the DC power source Vc. The DC power source Vc may limit the DC voltage provided by the DC power source 2 to be a preset voltage such as 5V. The bias voltage adjustment circuit 142 may shift the level of signal outputted by the voltage division circuit 140 according to the ratio of the resistor R3 to the resistor R4 and limit the voltage of signal supplied to the gain adjustment circuit 144 according to the forward bias of the DC power source Vc and the diode D1.

The gain adjustment circuit 144 comprises a resistor R5, a resistor R6, and an operational amplifier OPA. The first input end of the operational amplifier OPA is coupled with the resistor R3, the resistor R4, and the anode of the diode D1. The second input end of the operational amplifier OPA is coupled with the resistor R5 and the resistor R6. The other end of the resistor R5 is coupled with the negative end (−) of the DC power source 2 and the negative end (−) of the DC power source Vc. The other end of the resistor R6 is coupled with the output end of the operational amplifier OPA. The mid-point adjustment circuit 146 comprises a resistor R7 and a resistor R8. The resistor R7 and the resistor R8 are in series connection. The output end N3 of the signal detection module 14 is the node where the resistor R7 connects to the resistor R8. The other end of the resistor R7 is coupled with the positive end (+) of the DC power source Vc, the resistor R4, and the cathode of the diode D1. The other end of the resistor R8 is coupled with the negative end (−) of the DC power source 2, the resistor R2, and the negative end (−) of the DC power source Vc. The gain adjustment circuit 144 may increase the gain of the signal outputted by the bias voltage adjustment circuit 142. The DC power source Vc, the resistor R7, and the resistor R8 may adjust the voltage, which is supplied to the output end N3, to a mid-point of the preset voltage.

Accordingly, when the control module 12 determines that the switch sets are not short-circuited, and intends to select and enable the upper arm switch or the under arm switch of one of the switch sets, the second switching unit 304 may be turned on, so that the control module 12 may provide a first testing signal to the control end of the upper arm switch or the under arm switch of each of the switch sets sequentially to enable the selected upper arm switch or under arm switch. Moreover, the control module 12 may compare the waveform of the first testing signal with the waveform of the second detection signal generated by the signal detection module 14, to determine whether the selected upper arm switch or under arm switch malfunctions. If the selected upper arm switch or under arm switch malfunctions, the control module 12 may directly or indirectly turn off the first switching unit 302 and the second switching unit 304.

In one of the embodiments, the first detection signal may have a first voltage and a second voltage, and the first voltage may be larger than the second voltage. In one of the embodiments, when the control module 12 provides the first testing signal to the control end g1 of the upper arm switch M1, the control module 12 may compare the waveform of the first testing signal with the waveform of the second detection signal. In this case, if the first testing signal is the first voltage and the second detection signal is at the low level, it may indicate that the upper arm switch M1 is disconnected. In contrast, if the first testing signal is either the first voltage or the second voltage and the second detection signal is at the high level, it may indicate that the upper arm switch M1 is short-circuited. On the other hand, when the control module 12 provides the first testing signal to the control end g5 of the under arm switch M5, the control module 12 may compare the waveform of the first testing signal with the waveform of the second detection signal. In this case, if the first testing signal is the first voltage and the second detection signal is at the high level, it may indicate that the under arm switch M5 is disconnected. In contrast, if the first testing signal is either the first voltage or the second voltage and the second detection signal is at the low level, it may indicate that the under arm switch M5 is short-circuited.

In one of the embodiments, each of the switch sets may comprise a plurality of upper arm switches in parallel connection and a plurality of under arm switches in parallel connection (not shown in FIGs). When the control module 12 determines that the switch sets are not short-circuited, the control module 12 may select and enable the upper arm switches in parallel connection of one of the switch sets and the under arm switches in parallel connection of other one of the switch sets in the third stage of the detection process. Therefore, the control module 12 may determine whether the selected upper arm switches and the selected under arm switches malfunction, according to the second detection signal.

In more detail, when the control module 12 intends to select and enable the upper arm switches in parallel connection of one of the switch sets and the under arm switches in parallel connection of other one of the switch sets, the control module 12 may simultaneously provide a second detection signal to the control ends of the upper arm switches in parallel connection of one of the switch sets and to the control ends of the under arm switches in parallel connection of other one of the switch sets, and then may perform slope analysis on the second detection signal related with the upper arm switches in parallel connection and the second detection signal related with the under arm switches in parallel connection to determine the percentage of malfunctioned ones of the upper arm switches and the percentage of malfunctioned ones of the under arm switches.

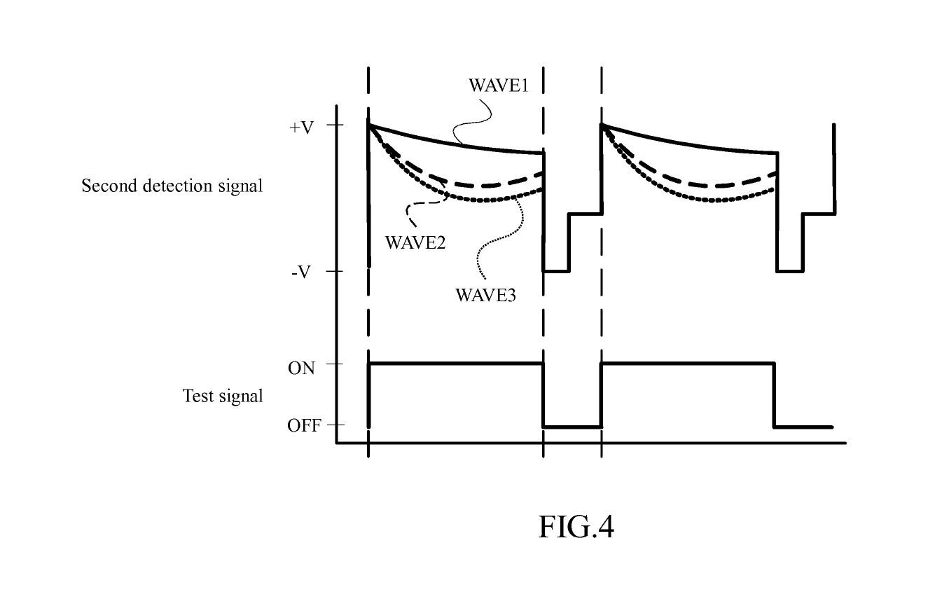

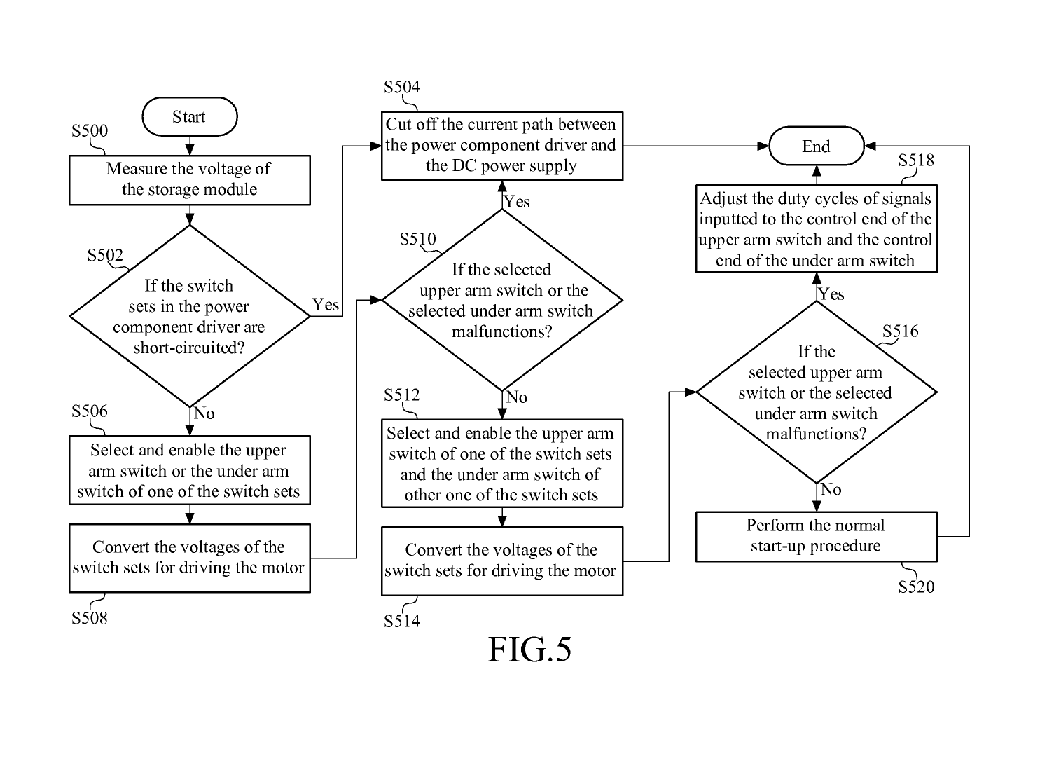

In one of the embodiments, FIG. 4 illustrates the waveform of the voltage outputted by the signal detection module 14 in FIG. 1. The waveform of the second detection signal in FIG. 4 is the simulated waveform associated with the percentage of malfunctions of the three upper arm switches in parallel or with the percentage of malfunctions of the three under arm switches in parallel. Assume the second detection signal is a square wave with a duty cycle. As shown in FIG. 4, WAVE1 represents the waveform of the second detection signal related with the three upper arm switches in parallel or the three under arm switches in parallel which work normally; WAVE2 represents the waveform of the second detection signal related with the three upper arm switches in parallel or the three under arm switches in parallel when one of the three upper arm switches or under arm switches in parallel is damaged; and WAVE3 represents the waveform of the second detection signal related with the three upper arm switches in parallel or the three under arm switches in parallel when two of the three upper arm switches or under arm switches in parallel are damaged.

Therefore, the control module 12 may adjust the duty cycles of the signals of the control ends of each upper arm switch and each under arm switch according to the percentage of malfunctioned ones of the selected upper arms switches and the under arm switches in parallel connection to further adjust the output power of the motor 6.

Referring to FIG. 5, one or more of embodiments of a detection method for power component drivers adapted to the detection device 1 in FIG. 1 is illustrated. The detection device 1 performs the detection method to detect whether the power component driver malfunctions.

Firstly, in step S500, the detection device 1 may measure the voltage of the storage module 4 to generate a first detection signal. In step S502, the detection device 1 may determine whether the switch sets in the power component driver 5 are short-circuited, according to the first detection signal. If the detection device 1 determines that one of the switch sets in the power component driver 5 is short-circuited, the detection device 1 may cut off the current path between the power component driver 5 and the DC power source 2 in step S504. In contrast, if the detection device 1 determines that the switch sets in the power component driver 5 are not short-circuited, the detection device 1 may select and enable the upper arm switch or the under arm switch of one of the switch sets in step S506.

Follow the step S506; in step S508, the detection device 1 may convert the voltage, which is provided by the switch sets to drive the motor 6, to generate a second detection signal. In step S510, the detection device 1 may determine whether the selected upper arm switch or the selected under arm switch malfunctions, according to the second detection signal. If the detection device 1 determines that the selected upper arm switch or under arm switch malfunctions, the detection method may return to the step S504; and if the detection device 1 determines that the selected upper arm switch or under arm switch functions normally, the detection device 1 may select and enable the upper arm switch of one of the switch sets and the under arm switch of other one of the switch sets in step S512.

Then, in step S514, the detection device 1 may convert the voltage, which is provided by the switch sets to drive the motor 6, to generate a second detection signal. In step S516, the detection device 1 may determine whether the selected upper arm switch and the selected under arm switch malfunction, according to the second detection signal obtained from the step S514. If the detection device 1 determines that the selected upper arm switch and the selected under arm switch malfunction, the detection device 1 may adjust the duty cycle of the signal supplied to the control ends of the upper arm switches and the control ends of the under arm switches in step S518; and if the detection device 1 determines that the selected upper arm switch and under arm switch functions normally, the power component driver 5 may perform the normal start-up procedure in step S520.

In summary, the disclosure provides a detection device for power component drivers, and a detection method thereof. Different stages of testing procedures are performed on the upper arm switches and under arm switches in the power component driver to determine the status of each upper arm switch and the status of each under arm switch. Furthermore, protecting procedures are performed on the upper arm switches and the under arm switches according to the status of each upper arm switch and the status of each under arm switch to prevent the damage of the power component driver or the motor.

What is claimed is:

1. A detection device, coupled with a direct current (DC) power source, a storage module, a power component driver, and a motor, wherein the power component driver comprises a plurality of switch sets, each of the plurality of switch sets comprises at least a upper arm switch and at least a under arm switch, and the detection device comprises:
a DC measuring module, coupled with the storage module, and configured to measure a voltage of the storage module to generate a first detection signal;
a control module, coupled with the DC measuring module and the power component driver, and configured to determine whether the plurality of switch sets are short-circuited, according to the first detection signal, and select and enable the at least one upper arm switch or the at least one under arm switch of one of the plurality of switch sets when the plurality of switch sets are not short-circuited; and
a signal detection module, coupled with the power component driver and the motor, and configured to convert a voltage, which is supplied by the plurality of switch sets to drive the motor, to generate a second detection signal according to which the control module determines whether the selected upper arm switch or under arm switch malfunctions.

2. The detection device according to claim 1, wherein a soft-start module is coupled with the DC power source, the DC measuring module, the storage module, and the power component driver, the soft-start module comprises a impedance unit, a first switching unit, and a second switching unit, the impedance unit is coupled with the DC power source and the first switching unit, and the impedance unit and the first switching unit are in parallel connection with the second switching unit; when the first switching unit turns on, the DC power source provides a DC voltage to a node between the storage module and the power component driver through a first current path so that the control module determines whether the plurality of switch sets are short-circuited, according to the first detection signal; and the control module turns on the second switching unit when the plurality of switch sets are not short-circuited, so that the DC power source to provide the DC voltage to the node through a second current path, and the control module selects and enables the upper arm switch or the under arm switch of the one of the plurality of switch sets.

3. The detection device according to claim 2, wherein the first switching unit and the second switching unit are controlled by the control module, and when the control module determines that the plurality of switch sets are short-circuited or that the selected upper arm switch or the selected under arm switch malfunctions, the control module turns off the first switching unit and the second switching unit.

4. The detection device according to claim 2, wherein the DC measuring module is further configured to measure a current of the first current path to generate the first detection signal according to which the control module determines whether the soft-start module functions normally.

5. The detection device according to claim 1, wherein when the control module selects and enables the upper arm switch or the under arm switch of the one of the plurality of switch sets, the control module sequentially selects and provides a testing signal to a control end of the upper arm switch or the under arm switch of each of the plurality of switch sets to enable the selected upper arm switch or the selected under arm switch; and when the control module, according to the second detection signal, determines whether the selected upper arm switch or the selected under arm switch malfunctions, the control module compares waveforms of the testing signal and the second detection signal to determine whether the selected upper arm switch or the selected under arm switch malfunctions.

6. The detection device according to claim 1, wherein the at least one upper arm switch in each of the plurality of switches comprises a plurality of upper arm switches in parallel, and the at least one under arm switch in each of the plurality of switches comprises a plurality of under arm switches in parallel; when the control module determines that the plurality of switch sets are not short-circuited, the control module selects and enables the plurality of upper arm switches of one of the plurality of switch sets and the plurality of under arm switches of other one of the plurality of switch set, to determine whether the selected upper arm switches and the selected under arm switches malfunction, according to the second detection signal.

7. The detection device according to claim 6, wherein when the control module selects and enables the plurality of upper arm switches of the one of the plurality of switch sets and the plurality of under arm switches of other one of the plurality of switch sets, the control module simultaneously selects and provides a testing signal to control ends of the plurality of upper arm switches of the one of the plurality of switch sets and control ends of the plurality of under arm switches of other one of the plurality of switch sets sequentially, to perform slope analysis on the second detection signal related with the plurality of upper arm switches and on the second detection signal related with the plurality of under arm switches, to determine a percentage of malfunctioned ones of the selected upper arm switches and a percentage of malfunctioned ones of the selected under arm switches.

8. The detection device according to claim 7, wherein the control module further adjusts a duty cycle of a signal inputted to the control ends of the plurality of upper arm switches and the plurality of under arm switches according to the percentage of the malfunctioned upper arm switches and the percentage of the malfunctioned under arm switches, to adjust an output power of the motor.

9. A detection method for determining whether a power component driver, which is coupled with a motor and a DC power source, malfunctions, comprising:
measuring a voltage of a storage module to generate a first detection signal, wherein the storage module is coupled with an input end of the power component driver;
determining whether a plurality of switch sets in the power component driver are short-circuited, according to the first detection signal, wherein each of the plurality of switch sets comprises at least a upper arm switch and at least a under arm switch;
selecting and enabling the at least one upper arm switch or the at least one under arm switch of one of the plurality of switch sets when the plurality of switch sets are not short-circuited;
converting a voltage, which is provided by the plurality of switch sets to drive the motor, to generate a second detection signal; and
determining whether the selected upper arm switch or the selected under arm switch malfunctions, according to the second detection signal.

10. The detection method according to claim 9, wherein a first current path and a second current path are between the DC power source and the input end, and before the voltage of the storage module is measured, the method further comprises:
providing a DC voltage to the input end through the first current path via the DC power source; and
providing the DC voltage to the input end through the second current path via the DC power source and selecting and enabling the at least one upper arm switch or the at least one under arm switch of the one of the plurality of switch sets when the plurality of switch sets are not short-circuited.

11. The detection method according to claim 10, wherein when the plurality of switch sets are short-circuited or when the selected upper arm switch or the selected under arm switch malfunctions, the first current path and the second current path are cut off.

12. The detection method according to claim 10, wherein to measure the voltage of the storage module comprises:
measuring a current on the first current path to generate the first detection signal; and
determining whether the first current path functions normally, according to the first detection signal.

13. The detection method according to claim 9, wherein when the plurality of switch sets are not short-circuited, to select and enable the at least one upper arm switch or the at least one under arm switch of the one of the plurality of switch sets comprises to sequentially provide a testing signal to a control end of the upper arm switch or the under arm switch of each of the plurality of switch sets to enable the selected upper arm switch or the selected under arm switch, and to determine whether the selected upper arm switch or the selected under arm switch malfunctions, according to the second detection signal is to compare waveforms of the testing signal and the second detection signal to determine whether the selected upper arm switch or the selected under arm switch malfunctions.

14. The detection method according to claim 9, wherein the at least one upper arm switch in each of the plurality of switch sets comprises a plurality of upper arm switches in parallel, the at least one under arm switch in each of the plurality of switch sets comprises a plurality of under arm switches in parallel, and when the plurality of switch sets are not short-circuited, the detection method further comprises:
selecting and enabling the plurality of upper arm switches of one of the plurality of switch sets and the plurality of under arm switches of other one of the plurality of switch sets;
converting a voltage, which is provided by the plurality of switch sets to drive the motor, to generate the second detection signal; and
determining whether the selected plurality of upper arm switches and the selected plurality of under arm switches malfunction, according to the second detection signal.

15. The detection method according to claim 14, wherein to select and enable the plurality of upper arm switches of one of the plurality of switch sets and the plurality of under arm switches of other one of the plurality of switch sets is to simultaneously provide a testing signal to control ends of the plurality of upper arm switches of one of the plurality of switch sets and control ends of the plurality of under arm switches of other one of the plurality of switch sets, and to determine whether the selected plurality of upper arm switches and the selected plurality of under arm switches malfunction, according to the second detection signal is to perform slope analysis on the second detection signal related with the selected plurality of upper arm switches and the second detection signal related with the selected plurality of under arm switches to determine a percentage of malfunctioned ones of the selected plurality of upper arm switches and a percentage of malfunctioned ones of the selected plurality of under arm switches.

16. The detection method according to claim 15, wherein after the percentage of malfunctioned ones of the selected plurality of upper arm switches and the percentage of malfunctioned ones of the selected plurality of under arm switches are determined, the detection method further comprises: to adjust a duty cycle of a signal inputted to the control end of each of the plurality of upper arm switches and the control end of each of the plurality of under arm switches according to the percentage of the malfunctioned upper arm switches and the percentage of the malfunctioned under arm switches to adjust an output power of the motor.

17. A detection device, coupled with a DC power source, a power component driver, and a motor, wherein the power component driver comprises a plurality of switch sets, each of the plurality of switch sets comprises a plurality of upper arm switches in parallel and a plurality of under arm switches in parallel, and the detection device comprises:
a control module, coupled with the power component driver, and configured to select and enable the plurality of upper arm switches of one of the plurality of switch sets and the plurality of under arm switches of other one of the plurality of switch sets when the plurality of switch sets are not short-circuited; and
a signal detection module, having an input end which is coupled with the power component driver and the motor, and an output end which is coupled with the control module, and configured to convert a voltage, which is provided by the plurality of switch sets to drive the motor, to generate a first detection signal when the plurality of switch sets are not short-circuited,
wherein the control module determines whether the selected upper arm switches or under arm switches malfunction, according to the first detection signal.

18. The detection device according to claim 17, wherein when the control module selects and enables the plurality of upper arm switches of one of the plurality of switch sets and the plurality of under arm switches of other one of the plurality of switch sets, the control module simultaneously provides a testing signal to control ends of the plurality of upper arm switches of one of the plurality of switch sets and the control ends of the plurality of under arm switches of other one of the plurality of switch sets, to perform slope analysis on the first detection signal relating to the selected upper arm switches and the first detection signal relating to the selected under arm switches to determine a percentage of malfunctioned ones of the selected upper arm switches and a percentage of malfunctioned ones of the selected under arm switches.

19. The detection device according to claim 18, wherein the control module further adjusts a duty cycle of a signal inputted to the control ends of the plurality of upper arm switches and the plurality of under arm switches according to the percentage of the malfunctioned upper arm switches and the percentage of the malfunctioned under arm switches to adjust an output power of the motor.

20. The detection device according to claim 17, wherein the detection device further comprises a DC measuring module, coupled with an input end of the power component driver and the control module, and configured to measure a voltage of a storage module coupled with the input end of the power component driver to generate a second detection signal according to which the control module determines whether the switch sets are short-circuited.

21. The detection device according to claim 20, wherein a soft-start module is coupled with the DC power source, the DC measuring module, the storage module, and the power component driver, the soft-start module comprises an impedance unit, a first switching unit, and a second switching unit, the impedance unit is coupled with the DC power source and the first switching unit, and the impedance unit and the first switching unit are connected with the second switching unit in parallel; when the first switching unit is turned on, the DC power source provides a DC voltage to the input end of the power component driver through a first current path, so that the control module determines whether the plurality of switch sets are short-circuited, according to the second detection signal; when the plurality of switch sets are not short-circuited, the control module turns on the second switching unit to enable the DC power source to provide the DC voltage to the input end of the power component driver through a second current path, so that the control module selects and enables the upper arm switches or the under arm switches of one of the plurality of switch sets or selects and enables the upper arm switches of one of the plurality of switch sets and the under arm switches of other one of the plurality of switch sets.

22. The detection device according to claim 21, wherein the first switching unit and the second switching unit are controlled by the control module, and when the control module determines that the plurality of switch sets are short-circuited or that the selected upper arm switches or under arm switches malfunction, the control module turns off the first switching unit and the second switching unit.

23. The detection device according to claim 21, wherein the DC measuring module is further configured to measure a current on the first current path to generate the second detection signal according to which the control module determines whether the soft-start module functions normally.

24. The detection device according to claim 17, wherein when the control module selects and enables the upper arm switches or the under arm switches of one of the plurality of switch sets, the control module sequentially provides a testing signal to control ends of the upper arm switches or the under arm switches of one of the plurality of switch sets to enable the selected upper arm switches or under arm switches; and when the control module, according to the first detection signal, determines whether the selected upper arm switches or under arm switches malfunction, the control module compares a waveform of the testing signal with a waveform of the first detection signal to determine whether the selected upper arm switches or under arm switches malfunction.

25. A detection method for determining whether a power component driver malfunctions, wherein the power component driver is coupled with a motor and a DC power source, and comprises a plurality of switch sets, each of the plurality of switch sets comprises a plurality of upper arm switches in parallel and a plurality of under arm switches in parallel, and the detection method comprises:
selecting and enabling the upper arm switches of one of the plurality of switch sets and the under arm switches of other one of the plurality of switch sets when the plurality of switch sets are not short-circuited;
converting a voltage, which is provided by the plurality of switch sets to drive the motor, to generate a first detection signal; and
determining whether the selected upper arm switches and the selected under arm switches malfunction, according to the first detection signal.

26. The detection method according to claim 25, wherein to select and enable the upper arm switches of one of the plurality of switch sets and the under arm switches of other one of the plurality of switch sets comprises: simultaneously providing a testing signal to control ends of the upper arm switches of one of the plurality of switch sets and the under arm switches of other one of the plurality of switch sets, to perform slope analysis on the first detection signal related with the upper arm switches and on the first detection signal related with the under arm switches to determine a percentage of malfunctioned ones of the selected upper arm switches and a percentage of malfunctioned ones of the selected under arm switches.

27. The detection method according to claim 26, further comprising: adjusting a duty cycle of a signal inputted to the control ends of the upper arm switches and the under arm switches according to the percentage of the malfunctioned upper arm switches and the percentage of the malfunctioned under arm switches to adjust an output power of the motor.

28. The detection method according to claim 25, wherein before to select and enable the upper arm switches of one of the plurality of switch sets and the under arm switches of other one of the plurality of switch sets, the detection method further comprises: measuring a voltage of a storage module coupled with an input end of the power component driver, to generate a second detection signal; and determining whether the plurality of switch sets are short-circuited, according to the second detection signal.

29. The detection method according to claim 28, wherein a first current path and a second current path are between the DC power source and the input end of the power component driver, and before the voltage of the storage module is measured, the detection method further comprises:
providing a DC voltage from the DC power source to the input end of the power component driver through the first current path; and
when the plurality of switch sets are not short-circuited, providing the DC voltage from the DC power source to the input end of the power component driver through the second current path, and selecting and enabling the upper arm switch or the under arm switch of one of the plurality of switch sets, or selecting and enabling the upper arm switches of one of the plurality of switch sets and the under arm switches of other one of the plurality of switch sets.

30. The detection method according to claim 29, wherein when the plurality of switch sets are short-circuited or when the selected upper arm switches or the selected under arm switches malfunction, the first current path and the second current path are cut off.

31. The detection method according to claim 29, further comprising: measuring a current flowing on the first current path to generate the second detection signal; and determining whether the first current path functions normally, according to the second detection signal.

32. The detection method according to claim 25, wherein to select and enable the upper arm switches or the under arm switches of one of the plurality of switch sets is to sequentially provide a testing signal to control ends of the upper arm switches or the under arm switches of one of the plurality of switch sets to enable the selected upper arm switches or the under arm switches; and to determine whether the selected upper arm switches or the selected under arm switches malfunction, according to the first detection signal is to compare a waveform of the testing signal with a waveform of the first detection signal to determine whether the selected upper arm switches or the selected under arm switches malfunction.
